(19) United States
(12) Patent Application Publication
(10) Pub. No.: US 2013/0141564 A1
(43) Pub. Date: Jun. 6, 2013

(54) PIEZOELECTRIC MOTOR, DRIVING DEVICE, ELECTRONIC COMPONENT INSPECTION DEVICE, ELECTRONIC COMPONENT CONVEYING DEVICE, PRINTING DEVICE, ROBOT HAND, AND ROBOT

(71) Applicant: Seiko Epson Corporation, Tokyo (JP)

(72) Inventor: Osamu MIYAZAWA, Shimosuwa (JP)

(73) Assignee: Seiko Epson Corporation, Tokyo (JP)

(21) Appl. No.: 13/705,929

(22) Filed: Dec. 5, 2012

(30) Foreign Application Priority Data
Dec. 6, 2011 (JP) 2011-266556

(51) Int. Cl. H01L 41/09; H04N 7/18

(52) U.S. Cl. CPC H01L 41/09; H04N 7/18; Y10S 901/19
USPC 348/126; 310/328

(57) ABSTRACT

A vibrating body which is formed of a piezoelectric material and has a convex portion in an end surface is accommodated in a vibrating body case, the convex portion of the vibrating body is pressed against an object along with the vibrating body case, and the vibrating body vibrates to drive the object. An end surface of a front-side pressure spring which presses the vibrating body case against a slide portion of a base is fitted into the vibrating body case such that the vibrating body case does not escape due to a reaction force during driving.

### BACKGROUND

1. Technical Field

The present invention relates to a piezoelectric motor, a driving device, an electronic component inspection device, an electronic component conveying device, a printing device, a robot hand, and a robot.

2. Related Art

A piezoelectric motor which vibrates a member (piezoelectric member) formed of a piezoelectric material to drive an object is known. The piezoelectric motor can be of small size compared to an electromagnetic motor which rotates a rotor by an electromagnetic force, can obtain a large driving force, and can align the object with high resolution. For this reason, the piezoelectric motor is used as an actuator for various devices, such as a driving mechanism of a camera (See JP-A-2008-187768 or the like).

The piezoelectric motor operates under the following principle. First, a piezoelectric member is formed to have a substantially rectangular parallelepiped shape, and has a convex portion in an end surface in a longitudinal direction. If a voltage with a predetermined frequency is applied to the piezoelectric member, vibration in which the piezoelectric member is stretched and vibration in which the piezoelectric member is bent are simultaneously generated. When this happens, the end surface of the piezoelectric member starts an elliptical motion to rotate in one direction. Accordingly, if the convex portion provided in the end surface is pressed against the object, the object can be moved in a given direction with a frictional force acting between the convex portion and the object.

For this reason, it is necessary for the piezoelectric motor to be used in a state where the convex portion provided in the end surface of the piezoelectric member is pressed against the object. It is also necessary to retain the piezoelectric member such that the piezoelectric member does not escape (dislodge) due to a reaction force received by the convex portion from the object when driving the object. Nevertheless, the vibration of the piezoelectric member should be permitted to the extent that the convex portion moves in an elliptical pattern. Accordingly, a structure in which the piezoelectric member is housed in a first case in a state where the convex portion protrudes, and the first case is housed in a second case in a slidable state is used (for example, JP-A-2009-33788). In this structure, the piezoelectric member is retained by the first case in a state where the vibration of the piezoelectric member is permitted, and the first case is pressed toward an object by a spring provided in the second case from a rear side. An opposite lateral surface of the first case is pressed against the inner wall surface of the second case from the lateral surface of the first case by a spring. In this way, the convex portion of the piezoelectric member can be pressed against the object along with the first case. The piezoelectric member is retained in the first case in a state where vibration is permitted, and the lateral surface of the first case is pressed against the inner wall surface of the second case by the spring. For this reason, even when the object is driven, there is no case where the piezoelectric member moves due to a reaction force received by the convex portion.

In recent years, however, there is increasing demand for a reduction in the size and an improvement in the performance of a device having a piezoelectric motor mounted therein. Accordingly, in regard to the piezoelectric motor, there is demand for further reduction in size and improvement in driving precision.

### SUMMARY

An advantage of some aspects of the invention is that it reduces the size of the piezoelectric motor and improves driving precision.

An aspect of the invention is directed to a piezoelectric motor which vibrates a vibrating body containing a piezoelectric material, and brings a convex portion protruding from an end surface of the vibrating body into contact with an object to move the object. The piezoelectric motor includes a vibrating body case which accommodates the vibrating body, a base which has a slide portion, on which the vibrating body case slides, and to which a vibrating body case is attached, a pressing elastic body which presses the convex portion protruding from the vibrating body case toward the object, and a side pressure elastic body which presses the vibrating body case toward the slide portion of the base from a direction intersecting a sliding direction of the vibrating body case, wherein an end surface of the side pressure elastic body in contact with the vibrating body case is fitted into the vibrating body case.

According to the piezoelectric motor having this configuration, the vibrating body vibrates in a state where the convex portion of the vibrating body is in contact with the object along with the vibrating body case, thereby moving the object. Since the vibrating body case is pressed against the slide portion of the base by the side pressure elastic body, there is no case where the vibrating body escapes due to a reaction force received by the convex portion from the object when driving the object. The vibrating body case may slide in a direction close to or away from the object. Nevertheless, the side pressure elastic body which presses the vibrating body case against the slide portion from a direction intersecting the sliding direction of the vibrating body case is configured such that the end surface on the side in contact with the vibrating body case is fitted into the vibrating body case.

With this, there is no case where the end surface of the side pressure elastic body relatively moves with respect to the vibrating body case. For this reason, since it is not necessary to provide an abrasion-resistant member or a roller between the end surface of the side pressure elastic body and the vibrating body case, the piezoelectric motor can be reduced in size. Of course, since the vibrating body case slides with respect to the object, in a structure in which the end surface of the side pressure elastic body is fitted into the vibrating body case, the side pressure elastic body presses the vibrating body case against the slide portion of the base, and generates a force in a direction inhibiting the sliding of the vibrating body case. This force may act in a direction changing the force which presses the convex portion of the vibrating body against the object, and may change a frictional force generated between the convex portion and the object, as a result, changing the driving force of the piezoelectric motor. However, in practice, the effect of change in frictional force due to slipping of the end surface of the side pressure elastic body on the vibrating body case or change in frictional force when the roller provided between the side pressure elastic body and the vibrating body case rolls is large. Accordingly, with a structure in which the end surface of the side pressure elastic body does not slip on the vibrating body case, rather, change in the force which presses the convex portion of the vibrating body against the object can be reduced. If the end surface of the side pressure elastic body is fitted into the vibrating body case, change in the pressing force of the convex portion by the side pressure elastic body is merely a value smaller than variation in the pressing force due to manufacturing variation of the pressing elastic body. For the above reason, with the use of the structure in which the end surface of the side pressure elastic body is fitted into the vibrating body case, it is possible to suppress change in the force which presses the convex portion of the vibrating body against the object. As a result, the driving force of the piezoelectric motor becomes stable, thereby moving the object by the same distance each time the convex portion performs an elliptical motion with the vibration of the vibrating body. For this reason, according to the aspect of the invention, it becomes possible to reduce the size of the piezoelectric motor and to improve driving precision.

It is sufficient that the pressing elastic body or the side pressure elastic body can press the vibrating body case, and various types of springs, such as a coil spring and a flat spring, may be used. When a flat spring is used as the side pressure elastic body, a portion in the surface of the side pressure elastic body which is in contact with the vibrating body case and exerts a force becomes the end surface of the side pressure elastic body. If the coil spring is used in a highly deformed state, even when the vibrating body case slides, the coil spring can be used in a state where the pressing force is hardly changed. For this reason, the coil spring can be preferably used as the pressing elastic body or the side pressure elastic body. It should suffice that the end surface of the side pressure elastic body is fitted so as to not slip on the vibrating body case when the vibrating body case slides. Accordingly, as the form in which the end surface of the side pressure elastic body is fitted into the vibrating body case, for example, a concave portion may be provided in the vibrating body case and the end surface of the pressure elastic body may be fitted into the concave portion, or a protrusion may be provided from the vibrating body case, and the end surface of the side pressure elastic body may be fitted into the protrusion. A protrusion may be provided from the end surface of the side pressure elastic body, and the protrusion may be fitted into a concave portion provided in the vibrating body case.

In the above-described piezoelectric motor, the end surface of the side pressure elastic body on a side not in contact with the vibrating body case may be supported by a side pressure elastic body retention portion, such that the end surface of the side pressure elastic body on a side in contact with the side pressure elastic body retention portion may be fitted into the side pressure elastic body retention portion.

With this, there is no case where the end surface of the side pressure elastic body on the side not in contact with the vibrating body case slips. For this reason, it is possible to avoid change in the frictional force due to slipping, and change in the force which presses the convex portion of the vibrating body against the object. As a result, it becomes possible to further improve driving precision of the piezoelectric motor.

In the above-described piezoelectric motor, instead of providing the pressing elastic body on the rear side of the vibrating body case (the opposite side to the side facing the object), the pressing elastic body may be provided on a side on which the slide portion is provided with respect to the vibrating body case or a side on which the side pressure elastic body is provided with respect to the vibrating body case.

With this, the length of the piezoelectric motor can be shortened compared to a case where the pressing elastic body is provided on the rear side of the vibrating body case. As a result, it becomes possible to further reduce the size of the piezoelectric motor.

A driving device, a printing device, a robot hand, a robot, or the like may be constituted by the above-described piezoelectric motor.

With the above-described piezoelectric motor, it is possible to realize reduction in size and high driving precision. Therefore, if the driving device, the printing device, the robot hand, the robot, or the like is constituted by the above-described piezoelectric motor, it is possible to obtain a driving device, a printing device, a robot hand, a robot, or the like which is of small size and has high performance.

An electronic component inspection device described below may be constituted by the above-described piezoelectric motor. That is, an electronic component inspection device which mounts a held electronic component in an inspection socket, and inspects the electrical characteristics of the electronic component may be configured to align the electronic component with respect to the inspection socket by the above-described piezoelectric motor.

As described above, since the piezoelectric motor according to the aspect of the invention can be of small size and can realize high driving precision, it becomes possible to align the electronic component with high precision and to realize a small electronic component inspection device.

Alternatively, the electronic component inspection device may be implemented as the following form. That is, an electronic component inspection device which mounts a held electronic component in an inspection socket, and inspects the electrical characteristics of the electronic component may be configured to include a piezoelectric motor which aligns the electronic component with respect to the inspection socket, wherein the piezoelectric motor includes a vibrating body which is formed to contain a piezoelectric material, and has a convex portion protruding from an end surface, a vibrating body case which accommodates the vibrating body, abase which has a slide portion on which the vibrating body case slides, and to which the vibrating body case is attached, a pressing elastic body which presses the convex portion protruding from the vibrating body case toward the object, and a side pressure elastic body which presses the vibrating body case toward the slide portion of the base from a direction intersecting a sliding direction of the vibrating body case, and an end surface of the side pressure elastic body on a side in contact with the vibrating body case is fitted into the vibrating body case.

The electronic component inspection device may be implemented as the following form. That is, an electronic component inspection device may be configured to include an inspection socket in which an electronic component is mounted, and the electrical characteristics of the electronic component are inspected, a holding device which holds an electronic component, a moving device which moves the holding device in the directions of three axes in total of a first axis and a second axis perpendicular to each other and a third axis perpendicular to the first axis and the second axis, an imaging device which is provided on the first axis or the second axis when viewed from the inspection socket, and detects a position in the directions of the first axis and the second axis and an angle around the third axis for the electronic component mounted in the inspection socket as the posture of the electronic component, an upstream-side stage which conveys the electronic component from the inspection socket to a predetermined position on the first axis or the second axis connecting the imaging device, a downstream-side stage which conveys the electronic component from a predetermined position opposite to the side on which the imaging device is provided when viewed from the inspection socket, and a control device which controls the operation of the moving device, wherein the control device includes a first control unit which moves the holding device holding the electronic component conveyed by the upstream-side stage onto the imaging device, a second control unit which moves the holding device to mount the electronic component whose posture is confirmed by the imaging device in the inspection socket, and a third control unit which moves the holding device to place the electronic component whose electrical characteristics are inspected in the inspection socket from the inspection socket to the downstream-side stage, the holding device has a first piezoelectric motor which moves the electronic component in the direction of the first axis on the basis of the posture of the electronic component detected by the imaging device, a second piezoelectric motor which moves the electronic component in the direction of the second axis on the basis of the posture of the electronic component detected by the imaging device, and a third piezoelectric motor which rotates the electronic component around the third axis on the basis of the posture of the electronic component detected by the imaging device, and the first to third piezoelectric motors are the above-described piezoelectric motor.

The electronic component inspection device having this configuration can mount the electronic component in the inspection socket after the posture of the electronic component is adjusted by the first to third piezoelectric motors provided in the holding device. Since the above-described piezoelectric motor can be of small size and can drive the object with high precision, the piezoelectric motor is particularly excellent as the first to third piezoelectric motors provided in the holding device.

The electronic component conveying device described below may be constituted by the piezoelectric motor according to the aspect of the invention. That is, an electronic component conveying device which conveys a held electronic component may be configured to align the electronic component by the piezoelectric motor according to the aspect of the invention.

As described above, since the piezoelectric motor according to the aspect of the invention can realize reduction in size and high driving precision, it becomes possible to align the electronic component with high precision and to realize a small electronic component conveying device.

Alternatively, an electronic component conveying device may be implemented as the following form. That is, an electronic component conveying device which conveys a held electronic component may be configured to includes a piezoelectric motor which aligns the electronic component, wherein the piezoelectric motor includes a vibrating body which is formed to contain a piezoelectric material, and has a convex portion protruding from an end surface, a vibrating body case which accommodates the vibrating body, a base which has a slide portion on which the vibrating body case slides, and to which the vibrating body case is attached, a pressing elastic body which presses the convex portion protruding from the vibrating body case toward the object, and a side pressure elastic body which presses the vibrating body case toward the slide portion of the base from a direction intersecting a sliding direction of the vibrating body case, and an end surface of the side pressure elastic body in contact with the vibrating body case is fitted into the vibrating body case.

The electronic component conveying device may be implemented as the following form. That is, an electronic component conveying device may be configured to include a holding device which holds an electronic component, a moving device which moves the holding device in the directions of three axes in total of a first axis and a second axis perpendicular to each other and a third axis perpendicular to the first axis and the second axis, and a control device which controls the operation of the moving device, wherein the holding device has a first piezoelectric motor which moves the electronic component in the direction of the first axis, a second piezoelectric motor which moves the electronic component in the direction of the second axis, and a third piezoelectric motor which rotates the electronic component around the third axis, and the first to third piezoelectric motors are the above-described piezoelectric motor.

### BRIEF DESCRIPTION OF THE DRAWINGS

Embodiments of the invention will be described with reference to the accompanying drawings, wherein like numbers reference like elements.

FIGS. 1A and 1B are explanatory views showing the basic configuration of a piezoelectric motor of this example.

FIG. 2 is an exploded view showing the structure of a main portion of this example.

FIGS. 3A to 3C are explanatory views showing an operation principle of a piezoelectric motor.

FIGS. 4A and 4B are explanatory views showing an attachment structure of a front-side pressure spring and a rear-side pressure spring of a piezoelectric motor of this example.

FIG. 5 is an explanatory view showing another form in which a front-side pressure spring and a rear-side pressure spring are attached.

FIGS. 6A to 6C are explanatory views showing a mode in which a main portion of a piezoelectric motor slides in an X direction, and a front-side pressure spring is bent.

FIG. 7 is a sectional view of a piezoelectric motor of a reference example in which rollers are provided between front-side and rear-side pressure springs and a second sidewall block.

FIGS. 8A to 8D are explanatory views illustrating a case where a concave portion into which a front-side pressure spring is fitted is not provided in a lateral surface of a vibrating body case.

FIGS. 9A to 9D are explanatory views illustrating a case where a concave portion into which a front-side pressure spring is fitted is not provided in a front housing.

FIG. 10 is an explanatory view illustrating another form in which a front-side pressure spring is attached in the front housing.

FIGS. 11A and 11B are sectional views of a piezoelectric motor taken at the position of the center axis of a front-side pressure spring.

FIG. 12 is a sectional view showing the structure of a piezoelectric motor of a first modification.

FIG. 13 is a sectional view showing the structure of a piezoelectric motor of a second modification.

FIG. 14 is a sectional view showing the structure of a piezoelectric motor of a third modification.

FIG. 15 is a sectional view showing the structure of a piezoelectric motor of a fourth modification.

FIG. 16 is a perspective view illustrating an electronic component inspection device embedded with a piezoelectric motor of this example.

FIG. 17 is an explanatory view of a fine adjustment mechanism embedded in a holding device.

FIG. 18 is a perspective view illustrating a printing device embedded with a piezoelectric motor of this example.

FIG. 19 is an explanatory view illustrating a robot hand embedded with a piezoelectric motor of this example.

FIG. 20 is an explanatory view illustrating a robot including a robot hand.

### DESCRIPTION OF EXEMPLARY EMBODIMENTS

Hereinafter, an example will be described in the following sequence.
A. Device Configuration
B. Operation Principle of Piezoelectric Motor
C. Side Pressure Spring Attachment Structure
D. Modifications
E. Application Examples

### A. Device Configuration

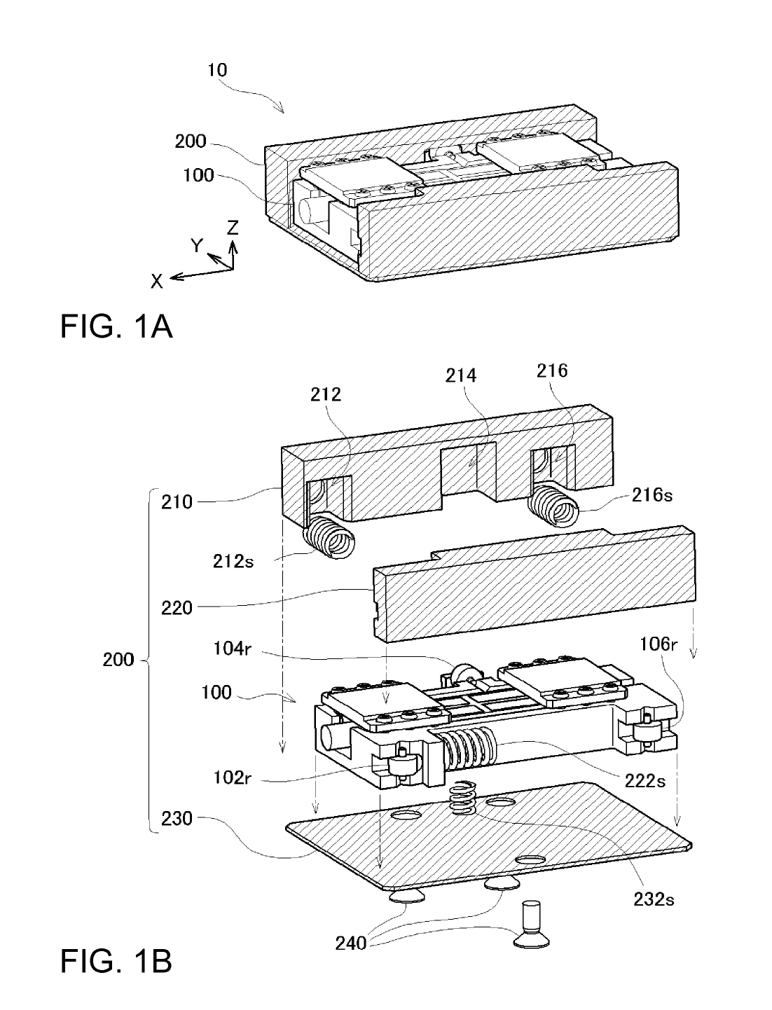

FIGS. 1A and 1B are explanatory views showing the basic configuration of a piezoelectric motor 10 of this example. FIG. 1A is an overall view of the piezoelectric motor 10 of this example, and FIG. 1B is an exploded view. As shown in FIG. 1A, the piezoelectric motor 10 of this example broadly has a main portion 100 and a base portion 200. The main portion 100 is attached into the base portion 200, and is slidable in one direction in this state. In this specification, the sliding direction of the main portion 100 is referred to as an X direction. As shown in the drawing, directions perpendicular to the X direction are respectively referred to as a Y direction and a Z direction.

The main portion 100 and the base portion 200 respectively have a plurality of components. For example, the base portion 200 is configured such that a first sidewall block 210 and a second sidewall block 220 are fastened to both sides of an upper surface of a substrate 230 having a substantially rectangular shape by locking screws 240 (see FIG. 1B). When assembling the piezoelectric motor 10, the first sidewall block 210 and the second sidewall block 220 are attached to the substrate 230 by the locking screws 240 from above the main portion 100.

The first sidewall block 210 has three concave portions forming a front housing 212, a central housing 214, and a rear housing 216. When attaching the first sidewall block 210 to the substrate 230, attachment is made in a state where a front-side pressure spring 212s is accommodated in the front housing 212, and a rear-side pressure spring 216s is accommodated in the rear housing 216. As a result, the main portion 100 is held in a state of being pressed to the second sidewall block 220 by the front-side pressure spring 212s and the rear-side pressure spring 216s. A front roller 102r and a rear roller 106r are attached onto the lateral surface side of the main portion 100 facing the second sidewall block 220. A pressure spring 222s is provided along the lateral surface of the main portion 100. The pressure spring 222s presses the main portion 100 at a location on the rear side of the front roller 102r in the X direction. In this example, the front-side pressure spring 212s and the rear-side pressure spring 216s correspond to the “side pressure elastic body” and “second biasing member” according to the invention, and the pressure spring 222s corresponds to the “pressing elastic body” and “first biasing member” according to the invention. The base portion 200 corresponds to the “base” according to the invention, and the first sidewall block 210 and the second sidewall block 220 constituting the base portion 200 respectively correspond to the “side pressure elastic body retention portion” and the “slide portion” according to the invention.

A pressing roller 104r in the Z direction (upward in the drawing) is provided on the lateral surface of the main portion 100 opposite to the side on which the front roller 102r and the rear roller 106r are provided. In a state where the first sidewall block 210 is attached, the pressing roller 104r is accommodated in the central housing 214 of the first sidewall block 210. A pressing spring 232s is provided between the rear side of a portion where the pressing roller 104r of the main portion 100 is provided and the substrate 230. For this reason, the pressing roller 104r is in a state of being pressed in the Z direction (upward in the drawing) with respect to the inner surface of the central housing 214.

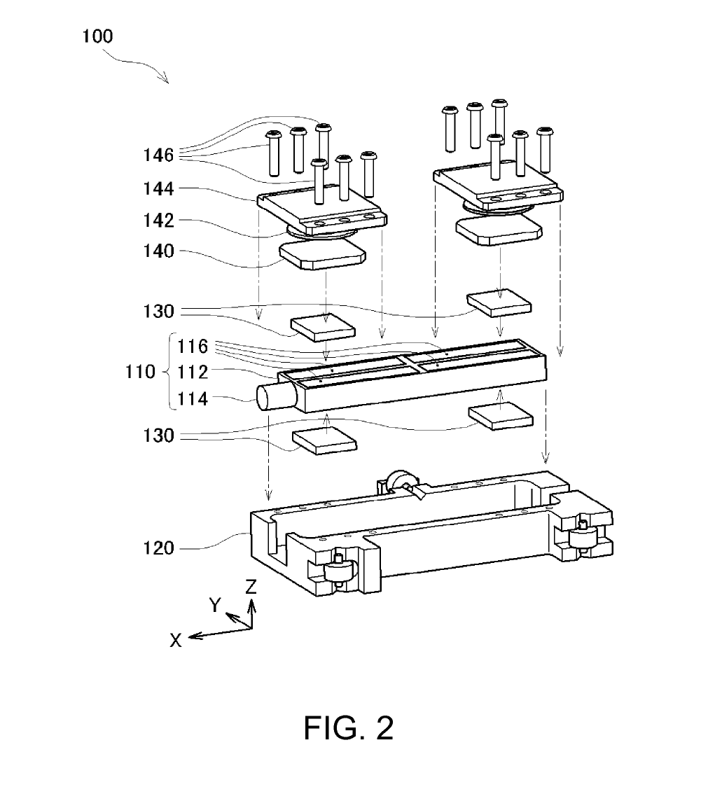

FIG. 2 is an exploded view showing the structure of the main portion 100 of this example. The main portion 100 broadly has a structure in which a vibration unit 110 is accommodated in the vibrating body case 120. The vibration unit 110 has a vibrating body 112 which is formed of a piezoelectric material to have a rectangular parallelepiped shape, a ceramic driving convex portion 114 (illustrated as a substantially cylindrical protrusion) which is attached to an end surface in a longitudinal direction (X direction) of the vibrating body 112, four front electrodes 116 which are provided by quartering one lateral surface of the vibrating body 112, and the like. Though not shown in FIG. 2, in the lateral surface opposite to the side on which the four front electrodes 116 are provided, a rear electrode which substantially covers the entire lateral surface is provided. The rear electrode is grounded. In this example, the driving convex portion 114 corresponds to the “convex portion” according to the invention.

The vibration unit 110 is accommodated in the vibrating body case 120 in a state where both lateral surfaces (in FIG. 2, both lateral surfaces in the Z direction) in which the front electrodes 116 and the rear electrode are provided are sandwiched by resin buffer members 130. Pressing plates 140, disk springs 142, and pressing lids 144 are placed from above the buffer members 130 on the front electrode 116 side, and the pressing lids 144 are fastened to the vibrating body case 120 by locking screws 146. For this reason, while the vibration unit 110 is pressed by the spring force of the disk springs 142, the resin buffer members 130 are shear-deformed, such that the vibrating body 112 is accommodated in the vibrating body case 120 in a vibratable state.

### B. Operation Principle of Piezoelectric Motor

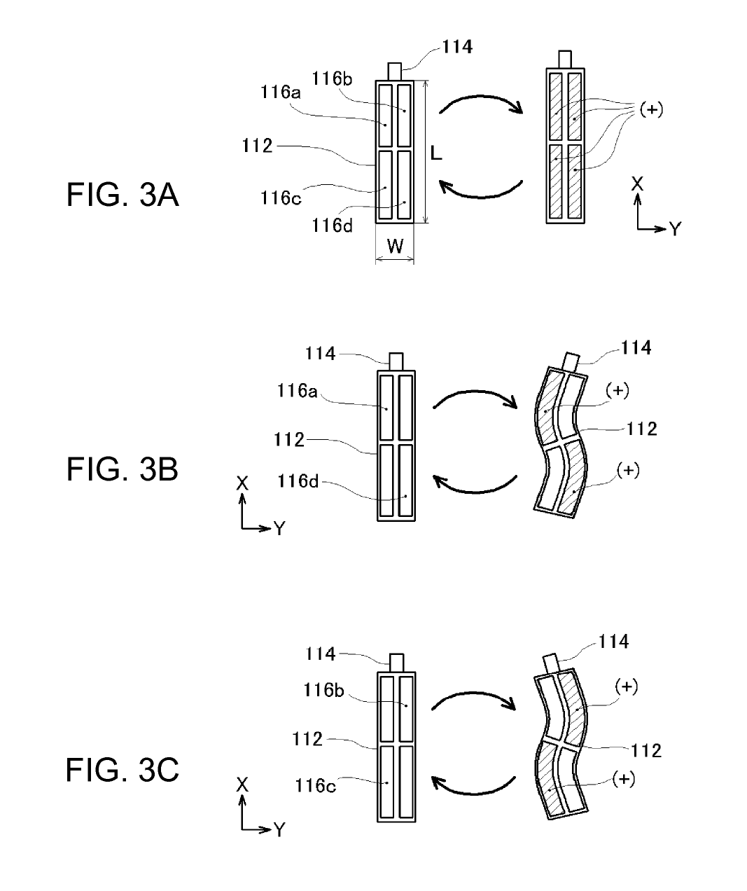

FIGS. 3A to 3C are explanatory views showing the operation principle of the piezoelectric motor 10. The piezoelectric motor 10 operates by the elliptical motion of the driving convex portion 114 of the vibration unit 110 when a voltage is applied to the front electrodes 116 of the vibration unit 110 in a given period. The elliptical motion of the driving convex portion 114 of the vibration unit 110 is for the following reason.

First, as well known in the art, the vibrating body 112 expands if a positive voltage is applied. Accordingly, as shown in FIG. 3A, if a positive voltage is applied to all of the four front electrodes 116, and the applied voltage is then released repeatedly, the vibrating body 112 repeatedly expands and contracts in the longitudinal direction (X direction). In this way, the operation in which the vibrating body 112 repeatedly expands and contracts in the longitudinal direction (X direction) is referred to as “stretching vibration”. If the frequency at which the positive voltage is applied is changed, the amount of expansion and contraction rapidly increases when a specific frequency is reached, and a type of resonance phenomenon occurs. The frequency (resonance frequency) at which resonance occurs due to stretching vibration is determined by the physical property of the vibrating body 112 and the dimension (width W, length L, thickness T) of the vibrating body 112.

As shown in FIG. 3B or 3C, the positive voltage is applied to a set of two front electrodes 116 diagonally opposite each other (a set of front electrode 116a and front electrode 116d or a set of front electrode 116b and front electrode 116c) in a given period. When this happens, the vibrating body 112 repeats an operation such that the tip portion in the longitudinal direction (X direction) (a portion to which the driving convex portion 114 is attached) shakes the head thereof in the right direction or the left direction in the drawing. For example, as shown in FIG. 3B, if the positive voltage is applied to the set of front electrode 116a and front electrode 116d in a given period, the vibrating body 112 repeats an operation such that the tip portion shakes in the right direction in the drawing. As shown in FIG. 3C, if the positive voltage is applied to the set of front electrode 116b and front electrode 116c in a given period, an operation such that the tip portion shakes in the left direction in the drawing is repeated. This operation of the vibrating body 112 is referred to as “bending vibration”. In regard to the bending vibration, there is the resonance frequency which is determined by the physical property of the vibrating body 112 and the dimension (width W, length L, thickness T) of the vibrating body 112. Accordingly, if the positive voltage is applied to the sets of two front electrodes 116 diagonally opposite to each other at the resonance frequency, the vibrating body 112 largely shakes the head thereof in the right direction or the left direction (Y direction).

The resonance frequency of the stretching vibration shown in FIG. 3A and the resonance frequency of the bending vibration shown in FIG. 3B or 3C are determined by the physical property of the vibrating body 112 or the dimension (width W, length L, thickness T) of the vibrating body 112. Accordingly, if the dimension (width W, length L, thickness T) of the vibrating body 112 is appropriately selected, the resonance frequencies can coincide with each other. If the voltage in the form of the bending vibration shown in FIG. 3B or 3C is applied to the vibrating body 112 at the resonance frequency, the bending vibration shown in FIG. 3B or 3C occurs, and the stretching vibration of FIG. 3A is induced by resonance. As a result, when a voltage is applied in the form shown in FIG. 3B, the tip portion (the portion to which the driving convex portion 114 is attached) of the vibrating body 112 starts an elliptical motion in a clockwise direction in the drawing. When a voltage is applied in the form shown in FIG. 3C, the tip portion of the vibrating body 112 starts an elliptical motion in a counterclockwise direction in the drawing.

The piezoelectric motor 10 drives the object by the elliptical motion. That is, the elliptical motion is generated in a state where the driving convex portion 114 of the vibrating body 112 is pressed against the object. In this case, the driving convex portion 114 repeats an operation to move from left to right (or from right to left) in a state of being pressed against the object when the vibrating body 112 expands, and to return to the original position in a state of being space apart from the object when the vibrating body 112 contracts. As a result, the object is driven in one direction by a frictional force applied from the driving convex portion 114. Since the driving force applied to the object is equal to a frictional force which is generated between the object and the driving convex portion 114, the magnitude of the driving force is determined by a frictional coefficient between the driving convex portion 114 and the object and a force when the driving convex portion 114 is pressed against the object.

As will be apparent from the operation principle of the piezoelectric motor 10 described above, the piezoelectric motor 10 is used in a state where the driving convex portion 114 is pressed against the object. For this reason, in the piezoelectric motor 10 of this example, the main portion 100 including the driving convex portion 114 is slidable with respect to the base portion 200, and the driving convex portion 114 protruding from the main portion 100 is pressed against the object by the pressure spring 222s provided between the main portion 100 and the base portion 200 (see FIGS. 1A and 1B).

If the object is driven, the driving convex portion 114 receives a reaction force from the object. The reaction force is transmitted to the main portion 100. As described above, while the main portion 100 should be slidable with respect to the base portion 200, if the main portion 100 escapes/dislodges in a direction perpendicular to the sliding direction with the reaction force received during driving, a sufficient driving force cannot be transmitted to the object. If the main portion 100 escapes, the amount of movement of the driving convex portion 114 decreases, such that the amount of driving of the object becomes small. Since the amount of escape of the main portion 100 may not be constantly stable, the amount of driving of the object becomes unstable. Accordingly, as shown in FIGS. 1A and 1B, in the piezoelectric motor 10 of this example, the main portion 100 is pressed against the second sidewall block 220 from the direction perpendicular to the sliding direction of the main portion 100 by the front-side pressure spring 212s and the rear-side pressure spring 216s. In the piezoelectric motor 10 of this example, the front-side pressure spring 212s and the rear-side pressure spring 216s are attached in the following manner.

### C. Side Pressure Spring Attachment Structure

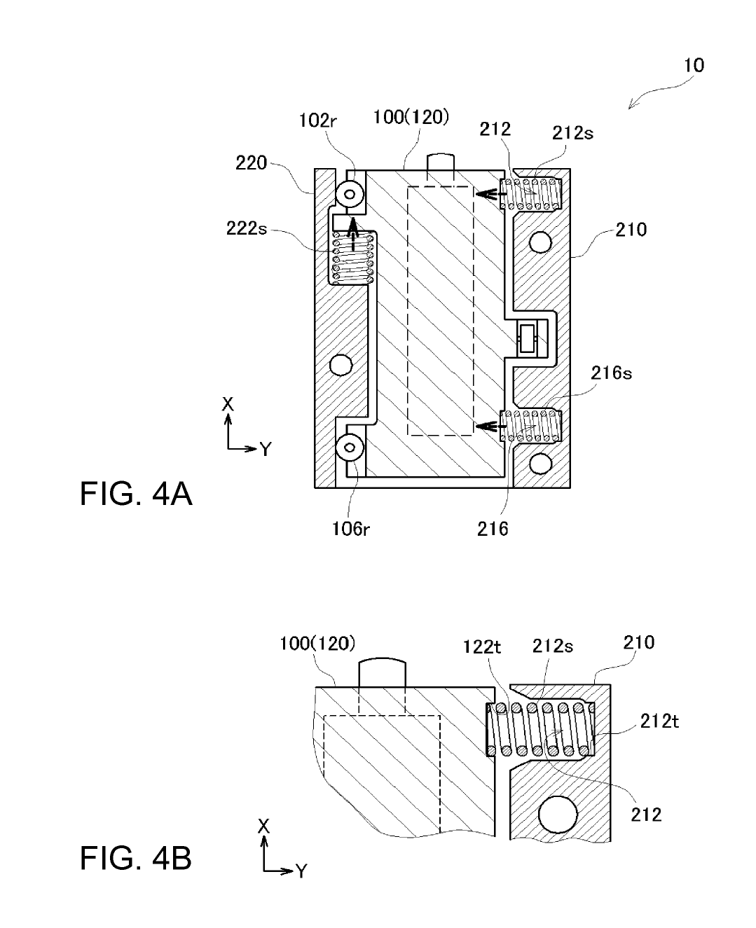

FIGS. 4A and 4B are explanatory views showing an attachment structure of the front-side pressure spring 212s and the rear-side pressure spring 216s in a sectional view of the piezoelectric motor 10 of this example. FIG. 4A shows a mode in which the pressure spring 222s is attached. As shown in FIG. 4A, the pressure spring 222s is provided between the main portion 100 (in practice, the vibrating body case 120 of the main portion 100) and the second sidewall block 220, and presses the main portion 100 in the X direction (upward in the drawing).

The front-side pressure spring 212s and the rear-side pressure spring 216s are provided between the main portion 100 (in practice, the vibrating body case 120) and the first sidewall block 210, and the main portion 100 is pressed against the second sidewall block 220 by the front-side pressure spring 212s and the rear-side pressure spring 216s. The front roller 102r and the rear roller 106r are provided between the main portion 100 and the second sidewall block 220. For this reason, the main portion 100 readily slides on the second sidewall block 220 in a state of being pressed against the second sidewall block 220. As a result, the vibrating body case 120 is slidable in the X direction in an aligned state in the Y direction.

The front-side pressure spring 212s is accommodated in the front housing 212 of the first sidewall block 210, and the rear-side pressure spring 216s is accommodated in the rear housing 216 of the first sidewall block 210. However, the front-side pressure spring 212s and the rear-side pressure spring 216s are accommodated in the front housing 212 and the rear housing 216 in a state where at least an end surface on the main portion 100 side (accurately, the vibrating body case 120) does not slip with respect to the vibrating body case 120, instead of being simply accommodated in the front housing 212 and the rear housing 216. In regard to an opposite end surface of each of the front-side pressure spring 212s and the rear-side pressure spring 216s (an end surface on the first sidewall block 210 side), the front-side pressure spring 212s and the rear-side pressure spring 216s are accommodated such that the end surface does not slip with respect to the first sidewall block 210 in the front housing 212 and the rear housing 216.

FIG. 4B is an enlarged sectional view of a portion where the front-side pressure spring 212s is accommodated in the front housing 212. As shown in the drawing, a circular concave portion 212t (recess) is formed in the inner wall surface on the deep side of the front housing 212 of the first sidewall block 210. The inner diameter of the concave portion 212t is nearly the same as the outer diameter of the front-side pressure spring 212s, and the end surface of the front-side pressure spring 212s is fitted into the concave portion 212t. Similarly, a circular concave portion 122t having nearly the same size as the outer diameter of the front-side pressure spring 212s is formed on the vibrating body case 120 side, and the end surface of the front-side pressure spring 212s is fitted into the concave portion 122t. The size of the front housing 212 has a margin with respect to the outer diameter of the front-side pressure spring 212s such that the front-side pressure spring 212s can move in the front housing 212.

Though not shown, in regard to the rear-side pressure spring 216s, similarly, concave portions are formed in the rear housing 216 and the vibrating body case 120, and the end surface of the rear-side pressure spring 216s is fitted into the concave portions. The size of the rear housing 216 has a margin with respect to the outer diameter of the rear-side pressure spring 216s.

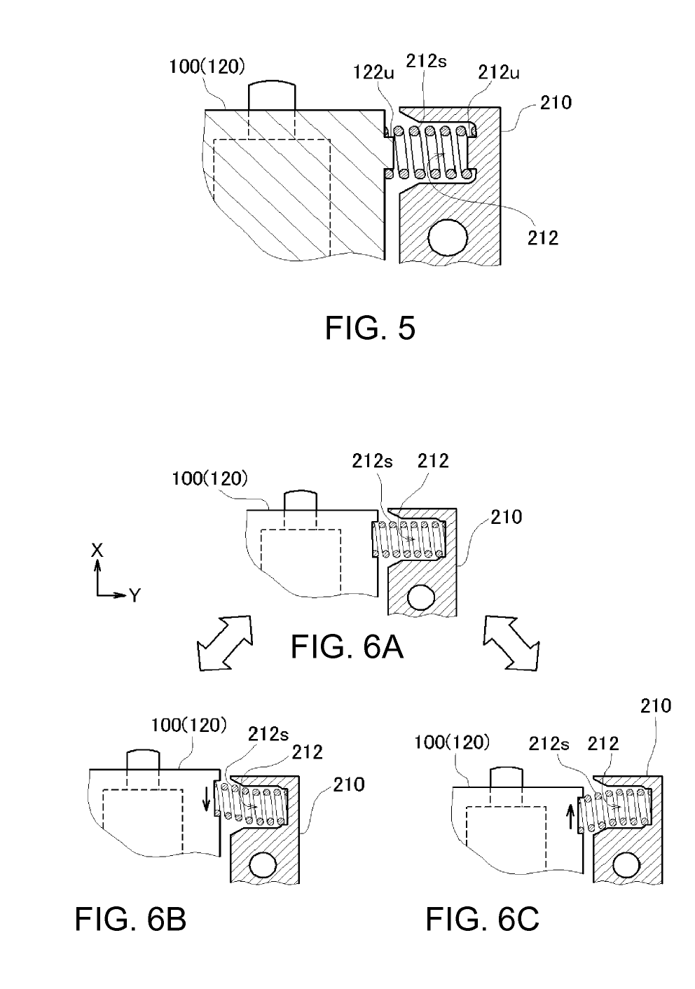

In this example, since the end surface of the front-side pressure spring 212s is fitted into the concave portions 212t and 122t formed in the front housing 212 and the vibrating body case 120, the end surface of the front-side pressure spring 212s is attached by the outer diameter portion. However, the invention is not limited to this method, and it should suffice that the end surface of the front-side pressure spring 212s can be attached. For example, as shown in FIG. 5, a convex portion 122u (a cylindrical protrusion) having an outer diameter corresponding to the inner diameter of the front-side pressure spring 212s may be provided to protrude from the vibrating body case 120, and the inner diameter of the front-side pressure spring 212s may be fitted into the convex portion 122u. A convex portion 212u having an outer diameter corresponding to the inner diameter of the front-side pressure spring 212s may be provided to protrude from the inner wall surface of the front housing 212, and the inner diameter of the front-side pressure spring 212s may be fitted into the convex portion 212u.

As described above, the main portion 100 is guided to the second sidewall block 220 and is slidable in the X direction. Accordingly, if the end surfaces of the front-side pressure spring 212s and the rear-side pressure spring 216s are attached so as to not slip with respect to at least the vibrating body case 120, when the main portion 100 slides in the X direction, the front-side pressure spring 212s and the rear-side pressure spring 216s are deformed to be bent. On the first sidewall block 210 side, if the end surfaces of the front-side pressure spring 212s and the rear-side pressure spring 216s are attached to the first sidewall block 210, when the main portion 100 slides, there is no case where the main portion 100 slips down the end surface on the first sidewall block 210 side, and the position of the front-side pressure spring 212s or the rear-side pressure spring 216s is misaligned. For this reason, along with sliding of the main portion 100, the front-side pressure spring 212s and the rear-side pressure spring 216s are deformed to be bent.

FIGS. 6A to 6C show a mode in which, in the piezoelectric motor 10 of this example, the main portion 100 slides in the X direction and the front-side pressure spring 212s is bent. FIG. 6A shows a state where the main portion 100 does not yet slide, and accordingly, the front-side pressure spring 212s is not bent. In this state, if the main portion 100 slides in the +X direction (upward in the drawing), the end surface of the front-side pressure spring 212s on the main portion 100 side moves to be dragged. As a result, as shown in FIG. 6B, the front-side pressure spring 212s is bent to be curved upward. On the contrary, in the state shown in FIG. 6A, if the main portion 100 slides in the −X direction (downward in the drawing), the front-side pressure spring 212s is bent to be curved downward as shown in FIG. 6C. The same applies to the rear-side pressure spring 216s.

As described above with reference to FIGS. 3A to 3C, the driving force of the piezoelectric motor 10 is determined by the frictional coefficient between the driving convex portion 114 and the object, and the force (the spring force of the pressure spring 222s) which presses the driving convex portion 114 against the object. As shown in FIG. 6B or 6C, if the front-side pressure spring 212s (and the rear-side pressure spring 216s) is bent, a reaction force in a direction weakening or intensifying the force pressing the driving convex portion 114 against the object is generated to the main portion 100. Accordingly, bending in the front-side pressure spring 212s and the rear-side pressure spring 216s may cause change in the driving force of the piezoelectric motor 10. Therefore, in order to exclude the factor for change in the driving force and to obtain the piezoelectric motor 10 having a stable driving force, a case where rollers are provided between the front-side and rear-side pressure springs 212s and 216s and the second sidewall block 220 is considered.

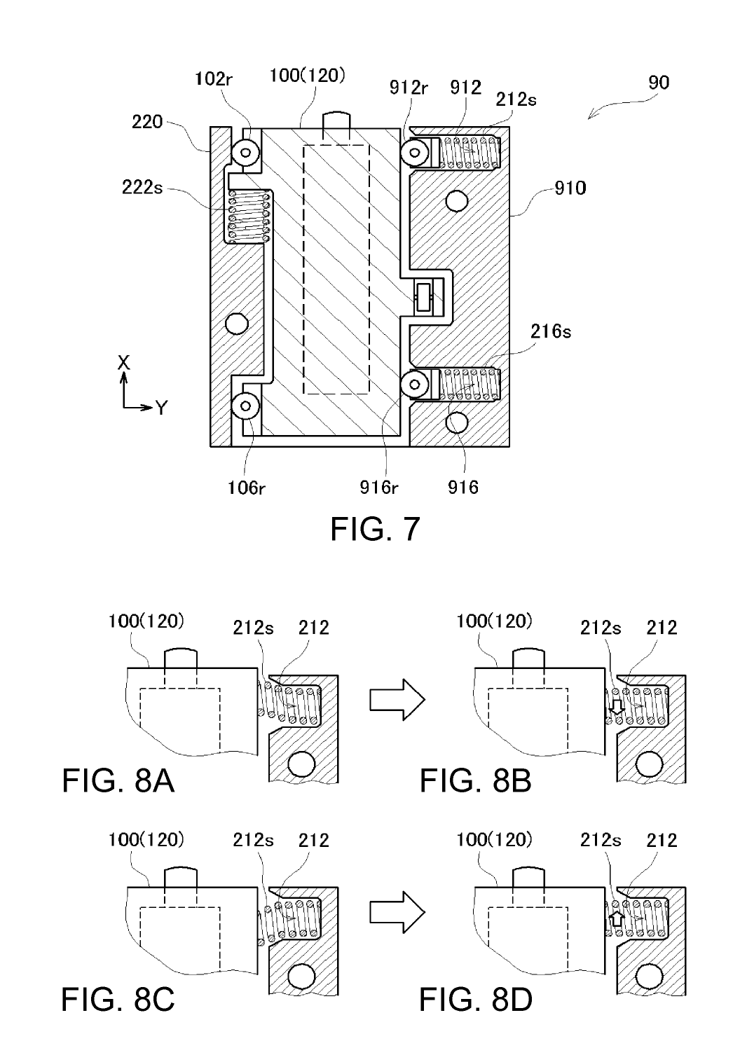

FIG. 7 is a sectional view of a piezoelectric motor 90 of a reference example in which rollers are provided between the front-side and rear-side pressure springs 212s and 216s and the second sidewall block 220. As shown in the drawing, in the piezoelectric motor 90 of the reference example, a front roller 912r is provided between the front-side pressure spring 212s and the main portion 100 (accurately, the vibrating body case 120), and a rear roller 916r is provided between the rear-side pressure spring 216s and the main portion 100 (the vibrating body case 120). The front roller 912r is accommodated in a front housing 912 of a first sidewall block 910 along with the front-side pressure spring 212s, and the rear roller 916r is accommodated in a rear roller 916r of the first sidewall block 910 along with the rear-side pressure spring 216s. Both end surfaces of the front-side pressure spring 212s are not attached to the front roller 912r and the first sidewall block 910, and both end surfaces of the rear-side pressure spring 216s are not attached to the rear roller 916r and the first sidewall block 910. All other parts in the piezoelectric motor 90 of the reference example are the same as those in the piezoelectric motor 10 of this example.

As will be apparent from comparison of the piezoelectric motor 90 of the reference example shown in FIG. 7 and the piezoelectric motor 10 of this example shown in FIGS. 4A and 4B, in the piezoelectric motor 90 of the reference example, as the front roller 912r and the rear roller 916r are further provided, the first sidewall block 910 increases in size by as much. For this reason, the piezoelectric motor 90 of the reference example is larger in size compared to the piezoelectric motor 10 of this example. In other words, the piezoelectric motor 10 of this example uses a structure in which the front-side pressure spring 212s and the rear-side pressure spring 216s directly press the main portion 100 (accurately, the vibrating body case 120) without the front roller 912r or the rear roller 916r, thereby reducing the size of the piezoelectric motor 10. If the front roller 912r or the rear roller 916r can be eliminated, the structure is simplified, making it possible to easily manufacture the piezoelectric motor 10.

When the structure in which the front-side pressure spring 212s and the rear-side pressure spring 216s directly press the main portion 100 is used, the front-side pressure spring 212s and the rear-side pressure spring 216s are bent due to sliding of the main portion 100. For this reason, it is seemingly considered that the driving force of the piezoelectric motor 10 is liable to change. However, a structure in which the front roller 912r and the rear roller 916r are eliminated from the piezoelectric motor 90 of the reference example, and at least the end surface of the front-side pressure spring 212s (and the rear-side pressure spring 216s) in contact with the vibrating body case 120 does not slip with respect to the vibrating body case 120 is made, thereby stabilizing the driving force and the amount of driving of the piezoelectric motor 10 for the following reason. A structure in which the end surface of the front-side pressure spring 212s (and the rear-side pressure spring 216s) in contact with the first sidewall block 210 does not slip with respect to the first sidewall block 210 is made, the effect can be more reliably exhibited. As a result, in the piezoelectric motor 10 of this example, a structure in which the front-side pressure spring 212s and the rear-side pressure spring 216s are in direct contact with the vibrating body case 120 and the first sidewall block 210, and the end surfaces of the front-side pressure spring 212s and the rear-side pressure spring 216s do not slip is used, thereby realizing reduction in size and ease of manufacturing of the piezoelectric motor 10 and realizing stabilization of the driving force and the amount of driving. Hereinafter, the reason will be described in detail.

First, the factor for which the main portion 100 slides in the X direction is, for example, that the driving convex portion 114 abrades during driving of the object, or that the driven object moves and the position of the object becomes close to or away from the piezoelectric motor 10. However, since the object which is driven by the piezoelectric motor 10 is usually supported from the rear side or guided by a guide member or the like, in practice, there is no case where the position of the object largely changes. The amount of abrasion of the driving convex portion 114 is slight. Accordingly, even when the main portion 100 slides in the X direction, the amount of sliding is slight. For this reason, even when the front-side pressure spring 212s and the rear-side pressure spring 216s are bent and affect the pressing force of the driving convex portion 114, the effect is slight. For example, since the spring constant varies about ±10% due to manufacturing variation of the pressure spring 222s pressing the driving convex portion 114 against the object, the pressing force of the driving convex portion 114 also varies at the same level (about ±10%). However, the effect of bending of the front-side pressure spring 212s and the rear-side pressure spring 216s becomes smaller than the effect of variation in the spring constant by at least one digit, and is at most estimated to be several times smaller than the effect of variation in the spring constant.

As described above, the major reason for which the main portion 100 slides is that, when the object is driven and moves, the position of the object becomes close to or away from the piezoelectric motor 10. From this, the main portion 100 slides in a form of vibrating with small amplitude. If a roller (the front roller 912r or the rear roller 916r) is used in a portion which slides in this form, a static friction state and a kinetic friction state are repeated in a portion of the outer circumference surface of the roller and the shaft supporting the roller, a coefficient of rolling friction changes irregularly. Since the coefficient of rolling friction changes between a coefficient of static friction and a coefficient of kinetic friction, the coefficient of rolling friction increases by more than two times or decreases to less than half. The force which presses the front-side pressure spring 212s and the rear-side pressure spring 216s against the main portion 100 is the force for pressing such that the main portion 100 does not move away from the second sidewall block 220 due to the reaction force received by the driving convex portion 114. For this reason, the spring force of the front-side pressure spring 212s and the rear-side pressure spring 216s should be about two times greater than the driving force applied to the object, and becomes a considerably great force. As a result, if the coefficient of rolling friction changes irregularly, the frictional force in the portion of the roller (the front roller 912r or the rear roller 916r) changes irregularly and largely, and largely affects the pressing force of the driving convex portion 114. In practice, as a result of estimation under a certain condition, the effect of change in the frictional force in the portion of the roller becomes equal to the effect of variation in the spring constant of the pressure spring 222s. Since the roller (the front roller 912r or the rear roller 916r) or the shaft supporting the roller cannot be manufactured such that the section is a complete circle, variation in the frictional force due to this reason is also superimposed.

For the above reason, as in the piezoelectric motor 90 of the reference example shown in FIG. 7, in a case in which the front-side pressure spring 212s and the rear-side pressure spring 216s press the main portion 100 through the front roller 912r or the rear roller 916r, the frictional force in the portion of the roller (the front roller 912r or the rear roller 916r) changes irregularly and largely, causing change in the pressing force of the driving convex portion 114. Meanwhile, as in the piezoelectric motor 10 of this example, even when the front-side pressure spring 212s and the rear-side pressure spring 216s directly press the main portion 100 without the rollers, there are few cases where the front-side pressure spring 212s and the rear-side pressure spring 216s are bent and affect the pressing force of the driving convex portion 114. Rather, the rollers are eliminated, thereby stabilizing the pressing force of the driving convex portion 114. As a result, it becomes possible to stabilize the driving force of the piezoelectric motor 10.

In the piezoelectric motor 10 of this example, the end surface of the front-side pressure spring 212s (and the rear-side pressure spring 216s) in contact with the main portion 100 (accurately, the vibrating body case 120) does not slip with respect to the vibrating body case 120. This is because the following is taken into consideration.

FIGS. 8A to 8D are explanatory views illustrating a case where the concave portion 122t into which the front-side pressure spring 212s is fitted is not provided in the lateral surface of the vibrating body case 120. Although in FIGS. 8A to 8D, only the front-side pressure spring 212s is shown, the same applies to the rear-side pressure spring 216s. When the concave portion 122t is not provided in the lateral surface of the vibrating body case 120, the end surface of the front-side pressure spring 212s is pressed against the lateral surface of the vibrating body case 120. For this reason, if the main portion 100 slides, the end surface of the front-side pressure spring 212s is dragged by the vibrating body case 120, and as a result, for example, as shown in FIG. 8A, the front-side pressure spring 212s is bent. However, the end surface of the front-side pressure spring 212s is merely pressed against the lateral surface of the vibrating body case 120, and during the operation of the piezoelectric motor 10, the main portion 100 constantly finely moves. For this reason, the end surface of the front-side pressure spring 212s dragged by the vibrating body case 120 may slip by some chance, and as shown in FIG. 8B, the front-side pressure spring 212s may be unbent. When this happens, it is not preferable in that the pressing force of the driving convex portion 114 changes discontinuously, and accordingly, the driving force of the piezoelectric motor 10 changes discontinuously.

As shown in FIG. 8C, there may be a case where, in a state where the front-side pressure spring 212s is assembled (a state where the main portion 100 does not slide), the front-side pressure spring 212s is bent and assembled. During the operation of the piezoelectric motor 10, since the main portion 100 constantly finely moves, the end surface of the front-side pressure spring 212s may slip by some chance, and as shown in FIG. 8D, the front-side pressure spring 212s may be unbent. In this case, it is not preferable in that the driving force of the piezoelectric motor 10 changes discontinuously.

Accordingly, in the piezoelectric motor 10 of this example, the concave portion 122t is provided in the lateral surface of the vibrating body case 120, and the end surface of the front-side pressure spring 212s is fitted into the concave portion 122t. For this reason, even when the main portion 100 slides and the front-side pressure spring 212s is bent, there is no case where the end surface of the front-side pressure spring 212s slips and the front-side pressure spring 212s is unbent. When assembling the front-side pressure spring 212s, since the end surface of the front-side pressure spring 212s is fitted into the concave portion 122t of the vibrating body case 120, there is no case where the front-side pressure spring 212s is assembled in a state where the front-side pressure spring 212s is bent. For this reason, it becomes possible to avoid a situation in which the driving force changes discontinuously during the operation of the piezoelectric motor 10.

In the above description, the end surface of the front-side pressure spring 212s (and the rear-side pressure spring 216s) on the vibrating body case 120 side has been described. The substantially same applies to the end surface of the front-side pressure spring 212s (and the rear-side pressure spring 216s) on the first sidewall block 210 side. That is, when the concave portion 212t is not formed in the front housing 212, and the end surface of the front-side pressure spring 212s can slip in the front housing 212, the driving force may abruptly change discontinuously during the operation of the piezoelectric motor 10. In regard to the rear-side pressure spring 216s, similarly, when the end surface of the rear-side pressure spring 216s can slip in the rear housing 216, the driving force may abruptly change discontinuously during the operation of the piezoelectric motor 10. Hereinafter, this point will be described supportively.

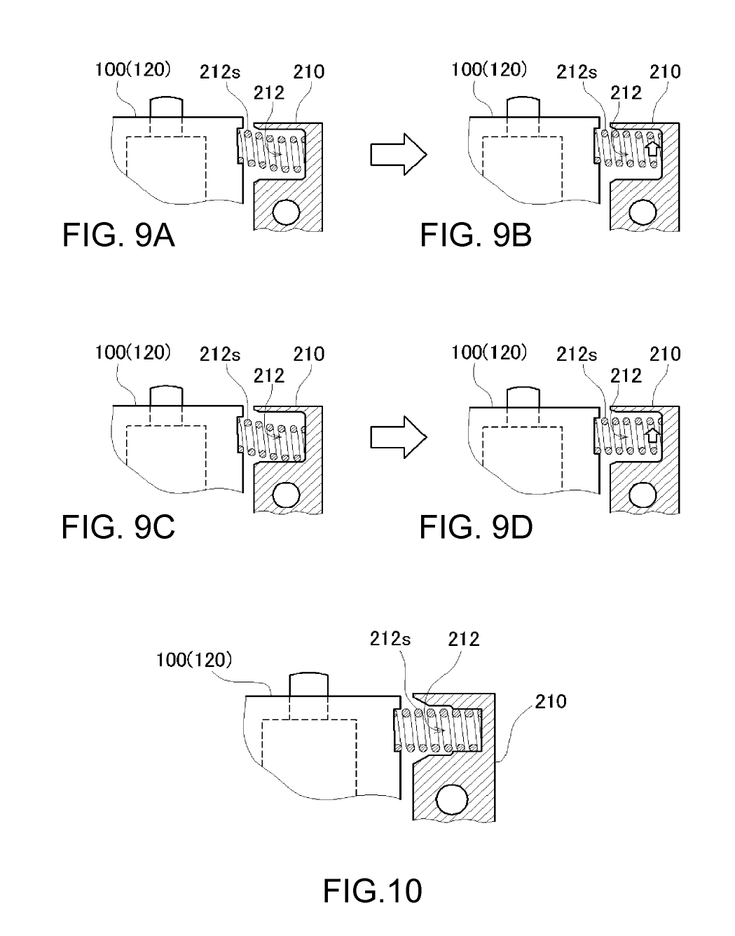

FIGS. 9A to 9D are explanatory views illustrating a case where the concave portion 212t into which the front-side pressure spring 212s is fitted is not provided in the front housing 212. Although in FIGS. 9A to 9D, only the front-side pressure spring 212s is shown, the same applies to the rear-side pressure spring 216s. Even when the concave portion 212t is not provided in the front housing 212, if the main portion 100 slides, as shown in FIG. 9A, the front-side pressure spring 212s is bent. However, when the end surface of the front-side pressure spring 212s is simply pressed against the first sidewall block 210 in the front housing 212, the end surface of the front-side pressure spring 212s may be dragged from the vibrating body case 120 side by some chance, and may slip in the front housing 212. As a result, as shown in FIG. 9B, the front-side pressure spring 212s may be unbent. When this happens, the pressing force of the driving convex portion 114 changes discontinuously, and the driving force of the piezoelectric motor 10 changes discontinuously.

As shown in FIG. 9C, when assembling the front-side pressure spring 212s, there may be a case where the front-side pressure spring 212s is not attached at a correct position in the front housing 212, and the front-side pressure spring 212s is bent. During the operation of the piezoelectric motor 10, the end surface of the front-side pressure spring 212s slips in the front housing 212 by some chance, and as shown in FIG. 9D, the front-side pressure spring 212s may be unbent. In this case, the driving force of the piezoelectric motor 10 changes discontinuously.

In the piezoelectric motor 10 of this example, taking into consideration this situation, as shown in FIGS. 4A and 4B, the concave portion 212t is provided in the front housing 212 of the first sidewall block 210, and the end surface of the front-side pressure spring 212s is fitted into the concave portion 212t. In regard to the rear-side pressure spring 216s, similarly, a concave portion 216t is provided in the rear housing 216, and the end surface of the rear-side pressure spring 216s is fitted into the concave portion 216t.

It should suffice that the end surfaces of the front-side pressure spring 212s and the rear-side pressure spring 216s do not slip in the front housing 212 and the rear housing 216, and the concave portion 212t or the concave portion 216t is not necessarily provided in the front housing 212 or the rear housing 216. For example, as shown in FIG. 10, at least the deep side of the front housing 212 is of a size corresponding to the outer diameter of the front-side pressure spring 212s, and the inner wall surface of the front housing 212 may be pressed against the outside of the front-side pressure spring 212s. In regard to the rear housing 216, similarly, at least the deep side of the rear housing 216 may be of size corresponding to the outer diameter of the rear-side pressure spring 216s, and the inner wall surface of the rear housing 216 may be pressed against the outside of the rear-side pressure spring 216s. In this way, since the end surfaces of the front-side pressure spring 212s and the rear-side pressure spring 216s do not slip in the front housing 212 and the rear housing 216, it is possible to avoid a situation in which the driving force abruptly changes discontinuously during the operation of the piezoelectric motor 10.

In the piezoelectric motor 10 of this example, as described above, the end surfaces of the front-side pressure spring 212s and the rear-side pressure spring 216s do not slip in the front housing 212 and the rear housing 216. However, unlike the end surface on the vibrating body case 120 side, for the purpose of ease of manufacturing of the piezoelectric motor 10, a structure in which the end surface does not slip may not be made in the front housing 212 and the rear housing 216. This is for the following reason.

First, when the vibrating body case 120 slides, the end surfaces of the front-side pressure spring 212s and the rear-side pressure spring 216s on the vibrating body case 120 side receive the force directly from the vibrating body case 120. Meanwhile, the end surfaces in the front housing 212 and the rear housing 216 merely receive the force indirectly from the vibrating body case 120 through the front-side pressure spring 212s and the rear-side pressure spring 216s. On the other hand, the force when the end surface is pressed by the spring force remains unchanged between the end surface on the vibrating body case 120 side and the end surface in the front housing 212 or the rear housing 216. Accordingly, the end surface on the vibrating body case 120 side has increasing slippability of the end surface. In other words, it is rare that, during the operation of the piezoelectric motor 10, the end surface of the front-side pressure spring 212s or the rear-side pressure spring 216s slips in the front housing 212 or the rear housing 216. Accordingly, the front housing 212 and the rear housing 216 may be formed without providing the concave portion 212t or the concave portion 216t in the front housing 212 or the rear housing 216 (see FIGS. 4A and 4B), without providing the convex portion 212u or the convex portion 216u (see FIG. 5), or without forming the portion on the deep side of the front housing 212 or the rear housing 216 narrow, thereby achieving more ease of manufacturing of the piezoelectric motor 10.

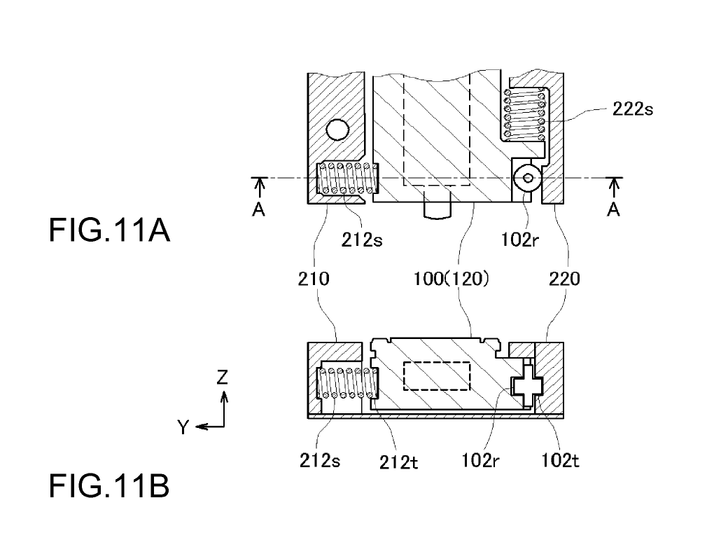

In the piezoelectric motor 10 of this example, the end surfaces of the front-side pressure spring 212s and the rear-side pressure spring 216s are attached so as to not slip with respect to the vibrating body case 120, the following advantages can be obtained. FIGS. 11A and 11B are sectional views of the piezoelectric motor 10 taken at the position of the center axis of the front-side pressure spring 212s. FIG. 11A is a top view showing a section position, and FIG. 11B is a sectional view. As shown in FIG. 11B, the end surface of the front-side pressure spring 212s on the vibrating body case 120 side is fitted into the concave portion 212t provided in the lateral surface of the vibrating body case 120. The front roller 102r is attached to the opposite lateral surface of the vibrating body case 120, and the front roller 102r is fitted into a roller groove 102t provided in the second sidewall block 220. For this reason, one side of the vibrating body case 120 is positioned in the Z direction (the up-down direction in the drawing) with the concave portion 212t by the front-side pressure spring 212s, and the other side is positioned in the Z direction with the roller groove 102t through the front roller 102r. Accordingly, the pressing roller 104r and the pressing spring 232s (see FIGS. 1A and 1B) which are provided so as to position the vibrating body case 120 can be eliminated. If the pressing roller 104r and the pressing spring 232s (see FIGS. 1A and 1B) are eliminated, since the structure of the piezoelectric motor 10 is further simplified, it becomes possible to achieve more ease of manufacturing and to further reduce the size of the piezoelectric motor 10. According to a structure in which the vibrating body case 120 is positioned with three front rollers 102r, the pressing roller 104r, and the rear roller 106r, the vibrating body case 120 is not always stably positioned taking into consideration processing errors of the roller and the surface (rolling surface) on the other side on which the roller rolls. Because the vibrating body case 120 is completely positioned by three points of a contact point of the front roller 102r and the second sidewall block 220, a contact point of the rear roller 106r and the second sidewall block 220, and a contact point of the pressing roller 104r and the second sidewall block 220. In this state, if the vibrating body case 120 slides in the X direction, the front roller 102r, the rear roller 106r, and the pressing roller 104r roll on the rolling surfaces of the second sidewall block 220. Of course, since there are processing errors in the rolling surfaces of the second sidewall block 220, a roller may be floated from the rolling surface. If the floated roller is pressed against the rolling surface, the posture of the vibrating body case 120 changes. Meanwhile, if the pressing roller 104r and the pressing spring 232s can be eliminated, it becomes possible to stably position the vibrating body case 120 without causing this problem.

In the piezoelectric motor 10 of this example, the pressure spring 222s which presses the main portion 100 in the X direction is provided lateral to the main portion 100 (in the Y direction with respect to the main portion 100) (see FIGS. 1A and 1B or FIGS. 4A and 4B). Since there are many cases where the main portion 100 is formed to be long in the X direction, in this way, it becomes possible to suppress the length in the X direction and to further reduce the size of the piezoelectric motor 10.

### D. Modifications

The piezoelectric motor 10 of this example has various modifications. Hereinafter, these modifications will be simply described. In the following modifications, a description will be provided focusing on the different portions from the piezoelectric motor 10 of this example. The same portions as those in the piezoelectric motor 10 of this example are represented by the same reference numerals, and a description thereof will be omitted.

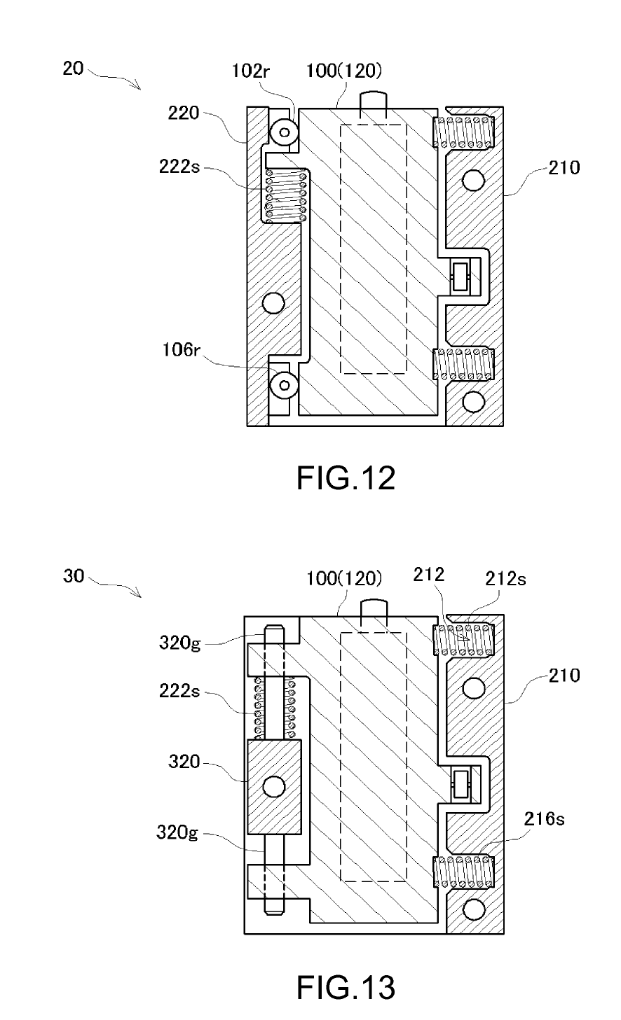

FIG. 12 is a sectional view showing the structure of a piezoelectric motor 20 of a first modification. In the piezoelectric motor 10 of the example shown in FIGS. 4A and 4B, the front roller 102r and the rear roller 106r are provided in the vibrating body case 120 side. Meanwhile, in the piezoelectric motor 20 of the first modification shown in FIG. 12, the front roller 102r and the rear roller 106r are provided in the second sidewall block 220 side. In this way, since the main portion 100 can be reduced in weight, the main portion 100 can easily slide in the X direction.

FIG. 13 is a sectional view showing the structure of a piezoelectric motor 30 of a second modification. In the piezoelectric motor 30 of the second modification, a guide pole 320g extends from a second sidewall block 320, and the sliding of the main portion 100 is guided by the guide pole 320g. In this way, the structure of the piezoelectric motor 30 can be further simplified.

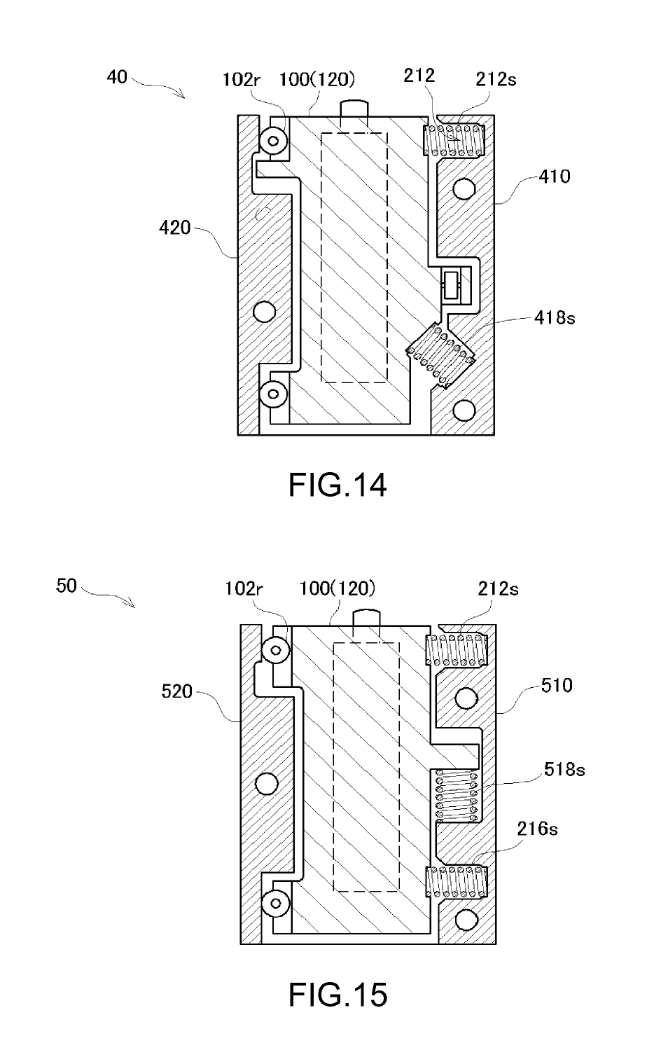

FIG. 14 is a sectional view showing the structure of a piezoelectric motor 40 of a third modification. In the piezoelectric motor 40 of the third modification, a pressure spring 418s is provided obliquely with respect to the main portion 100. In this way, with the single pressure spring 418s, while the main portion 100 can be pressed against the object, the main portion 100 can be pressed against a second sidewall block 420. For this reason, as shown in FIG. 14, the pressure spring 418s can serve as the rear-side pressure spring 216s, and the piezoelectric motor 40 can be further reduced in size. Of course, in addition to the rear-side pressure spring 216s, if the pressure spring 418s serves as the front-side pressure spring 212s, since the front-side pressure spring 212s can be further eliminated from the state shown in FIG. 14, it becomes possible to reduce the size of the piezoelectric motor 40.

FIG. 15 is a sectional view showing the structure of a piezoelectric motor 50 of a fourth modification. In the piezoelectric motor 40 of the fourth modification, a pressure spring 518s is provided on the same side of the main portion 100 as the front-side pressure spring 212s and the rear-side pressure spring 216s. Accordingly, the pressing roller 104r or the pressing spring 232s provided in the piezoelectric motor 10 of this example is eliminated. In this way, since the structure of a second sidewall block 520 is simplified, it is possible to further reduce the size of the piezoelectric motor 50. Since the movement of the main portion 100 in the Z direction (in FIG. 15, a direction perpendicular to paper) is restricted by the front-side pressure spring 212s and the rear-side pressure spring 216s, there is no problem even when the pressing roller 104r and the pressing spring 232s are eliminated.

### E. Application Examples

The piezoelectric motor 10 of this example or the piezoelectric motors 20, 30, 40, and 50 of the various modifications can have a small size but can drive the object with high precision. Therefore, the piezoelectric motor can be suitably incorporated as a driving device in the following devices, for example.

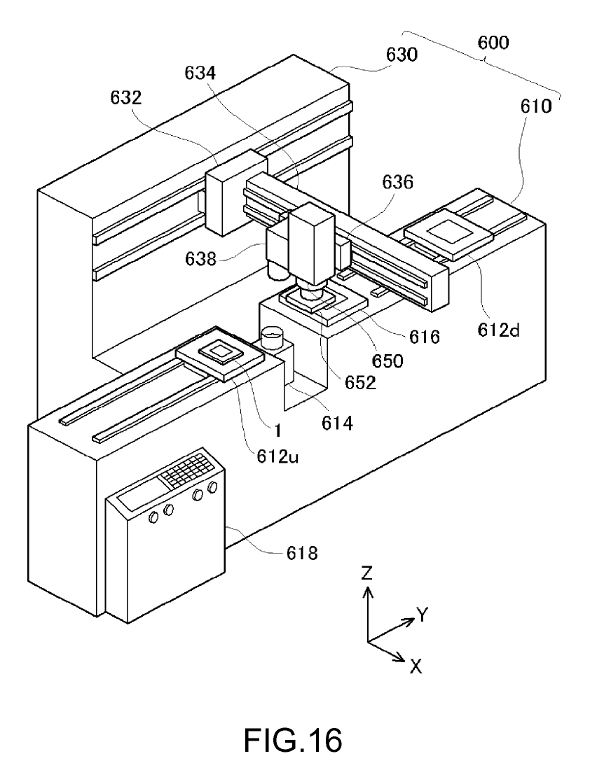

FIG. 16 is a perspective view illustrating an electronic component inspection device 600 in which the piezoelectric motor 10 of this example is incorporated. The electronic component inspection device 600 broadly includes a base 610, and a support 630 which is provided upright on the lateral surface of the base 610. On the upper surface of the base 610 are provided an upstream-side stage 612u which is conveyed with an electronic component 1 to be inspected placed thereon, and a downstream-side stage 612d which is conveyed with the inspected electronic component 1 placed thereon. Between the upstream-side stage 612u and the downstream-side stage 612d are provided an imaging device 614 which confirms the posture of the electronic component 1, and an inspection table 616 on which the electronic component 1 is set so as to inspect electrical characteristics. Representative examples of the electronic component 1 include “semiconductors”, “display devices, such as CLD or OLED”, “crystal devices”, “various sensors”, “ink jet heads”, “various MEMS devices”, and the like. The inspection table 616 of this example corresponds to the “inspection socket” according to the invention.

A Y stage 632 is provided in the support 630 to be movable in a direction (Y direction) parallel to the upstream-side stage 612u and the downstream-side stage 612d of the base 610, and an arm portion 634 extends from the Y stage 632 in a direction (X direction) toward the base 610. An X stage 636 is provided on the lateral surface of the arm portion 634 to be movable in the X direction. An imaging camera 638 and a holding device 650 embedded with a Z stage movable in an up-down direction (Z direction) are provided in the X stage 636. A holding portion 652 which holds the electronic component 1 is provided at the tip of the holding device 650. A control device 618 which controls the overall operation of the electronic component inspection device 600 is provided on the front surface side of the base 610. In this example, the Y stage 632 provided in the support 630, the arm portion 634, the X stage 636, or the holding device 650 corresponds to the “electronic component conveying device” according to the invention. In this example, the X stage 636, the Y stage 632, and the Z stage embedded in the holding device 650 correspond to the “moving device” according to the invention. The control device 618 of this example corresponds to the “first control unit”, the “second control unit”, and the “third control unit” according to the invention.

The electronic component inspection device 600 having the above configuration inspects the electronic component 1 as follows. First, the electronic component 1 to be inspected is placed on the upstream-side stage 612u and moves near the inspection table 616. Next, the Y stage 632 and the X stage 636 are driven to move the holding device 650 to a position directly above the electronic component 1 placed on the upstream-side stage 612u. At this time, the position of the electronic component 1 can be confirmed using the imaging camera 638. The holding device 650 falls using the Z stage embedded in the holding device 650, if the electronic component 1 is held using the holding portion 652, the holding device 650 moves directly above the imaging device 614, and the posture of the electronic component 1 is confirmed using the imaging device 614. Subsequently, the posture of the electronic component 1 is adjusted using a fine adjustment mechanism embedded in the holding device 650. The holding device 650 moves to above the inspection table 616, and then the Z stage embedded in the holding device 650 is driven to set the electronic component 1 on the inspection table 616. Since the posture of the electronic component 1 is adjusted using the fine adjustment mechanism in the holding device 650, it is possible to set the electronic component 1 at a correct position of the inspection table 616. After the electrical characteristics of the electronic component 1 are inspected using the inspection table 616, the electronic component 1 is excluded from the inspection table 616, the Y stage 632 and the X stage 636 are driven to move the holding device 650 to above the downstream-side stage 612d, and the electronic component 1 is placed on the downstream-side stage 612d. Thereafter, the downstream-side stage 612d is driven to convey the inspected electronic component 1 to a predetermined position.

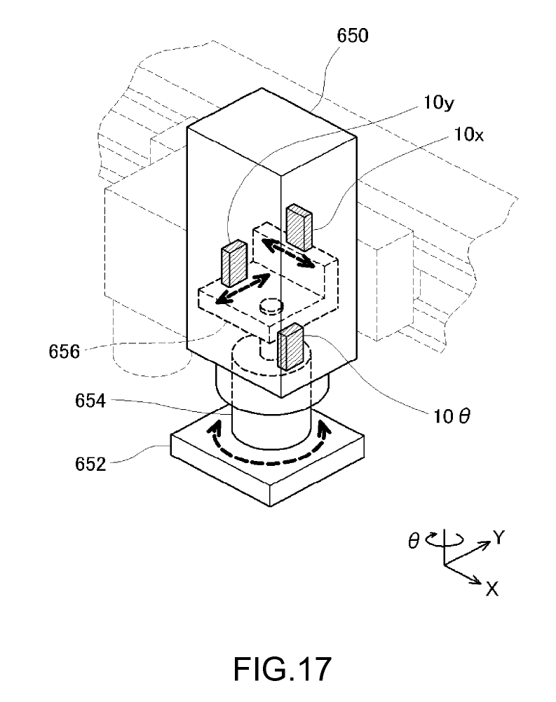

FIG. 17 is an explanatory view of the fine adjustment mechanism embedded in the holding device 650. As shown in the drawing, in the holding device 650 are provided a rotation shaft 654 connected to the holding portion 652, and a fine adjustment plate 656 to which the rotation shaft 654 is rotatably attached. The fine adjustment plate 656 is movable in the X direction and the Y direction using a guide mechanism (not shown).

As indicated by hatching in FIG. 17, a piezoelectric motor 10θ for a rotation direction toward the end surface of the rotation shaft 654 is mounted, and the driving convex portion (not shown) of the piezoelectric motor 10θ is pressed against the end surface of the rotation shaft 654. For this reason, if the piezoelectric motor 10θ is operated, it becomes possible to rotate the rotation shaft 654 (and the holding portion 652) in a θ direction by an arbitrary angle with high precision. A piezoelectric motor 10x for the X direction toward the fine adjustment plate 656 and a piezoelectric motor 10y for the Y direction are provided, and the driving convex portions (not shown) of the piezoelectric motors 10x and 10y are pressed against the surface of the fine adjustment plate 656. For this reason, if the piezoelectric motor 10x is operated, it becomes possible to move the fine adjustment plate 656 (and the holding portion 652) in the X direction by an arbitrary distance with high precision. Similarly, if the piezoelectric motor 10y is operated, it becomes possible to move the fine adjustment plate 656 (and the holding portion 652) in the Y direction by an arbitrary distance with high precision. Accordingly, in the electronic component inspection device 600 of FIG. 16, if the piezoelectric motor 10θ, the piezoelectric motor 10x, and the piezoelectric motor 10y are operated, it is possible to finely adjust the posture of the electronic component 1 held by the holding portion 652. In this example, the piezoelectric motor 10x and the piezoelectric motor 10y respectively correspond to the “first piezoelectric motor” and “second piezoelectric motor” according to the invention, and the piezoelectric motor 10θ corresponds to the “third piezoelectric motor” according to the invention. The rotation shaft 654 or the fine adjustment mechanism having the fine adjustment plate 656, the piezoelectric motor 108, the piezoelectric motor 10x, and the piezoelectric motor 10y corresponds to the “driving device” according to the invention.

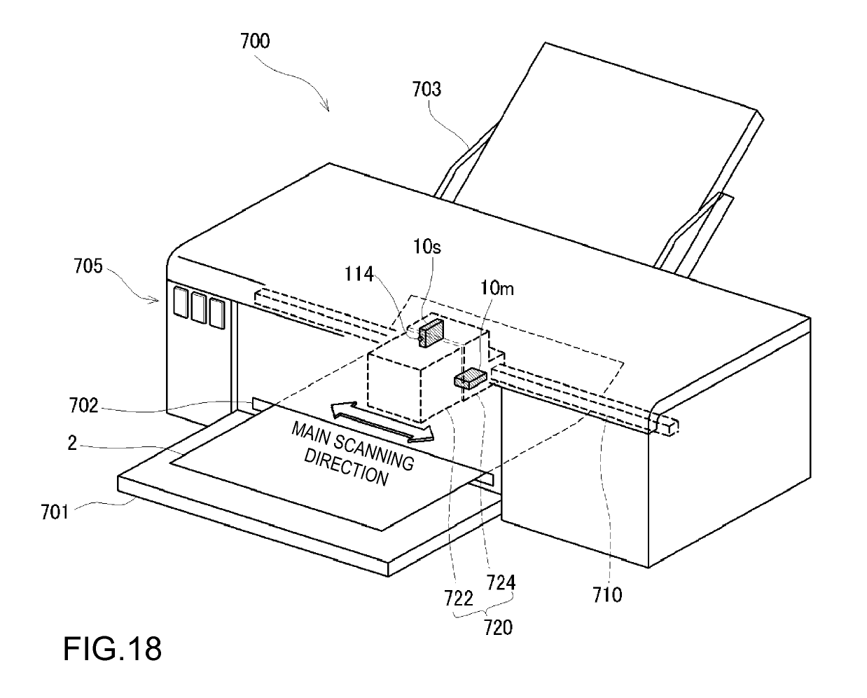

FIG. 18 is a perspective view illustrating a printing device 700 in which the piezoelectric motor 10 of this example is incorporated. The printing device 700 is a so-called ink jet printer which ejects ink onto the surface of a printing medium 2 to print an image. The printing device 700 substantially has a boxlike appearance shape, and is provided with a sheet discharge tray 701 substantially at the center of the front surface, a discharge port 702, and a plurality of operation buttons 705. A feed tray 703 is provided on the rear surface side. If the printing medium 2 is set in the feed tray 703 and the operation button 705 is operated, the printing medium 2 is drawn from the feed tray 703, an image is printed on the printing medium 2 inside the printing device 700, and the printing medium 2 is discharged from the discharge port 702.

Inside the printing device 700 are provided a carriage 720 which reciprocates in a main scanning direction on the printing medium 2, and a guide rail 710 which guides the movement of the carriage 720 in the main scanning direction. The carriage 720 has an ejection head 722 which ejects ink onto the printing medium 2, a driving unit 724 which drives the carriage 720 in the main scanning direction, and the like. A plurality of ejection nozzles are provided on the bottom surface side (the side toward the printing medium 2) of the ejection head 722, such that ink can be ejected from the ejection nozzles toward the printing medium 2. Piezoelectric motors 10m and 10s are mounted in the driving unit 724. The driving convex portion (not shown) of the piezoelectric motor 10m is pressed against the guide rail 710. For this reason, if the piezoelectric motor 10m is operated, it is possible to move the carriage 720 in the main scanning direction. The driving convex portion 114 of the piezoelectric motor 10s is pressed with respect to the ejection head 722. For this reason, if the piezoelectric motor 10s is operated, the bottom surface side of the ejection head 722 can be close to the printing medium 2 or can be away from the printing medium 2. In the printing device 700 which uses so-called roll paper as the printing medium 2, a mechanism for cutting roll paper with the image printed thereon is required. In this case, if a cutter is attached to the carriage 720 and moved in the main scanning direction, it is possible to cut roll paper.

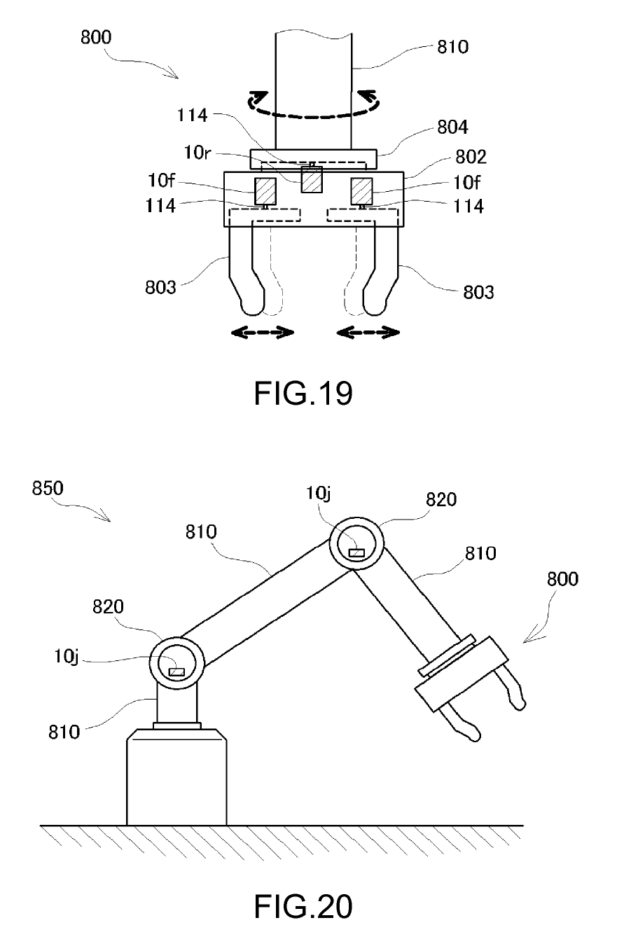

FIG. 19 is an explanatory view illustrating a robot hand 800 in which the piezoelectric motor 10 of this example is incorporated. In the robot hand 800, a plurality of finger portions 803 are provided upright from a base 802, and are connected to an arm 810 through a wrist 804. A root portion of each finger portion 803 is movable in the base 802, and a piezoelectric motor 10f is mounted in a state where a driving convex portion 114 is pressed against the root portion of the finger portion 803. For this reason, if the piezoelectric motors 10f are operated, the finger portions 803 can be moved to hold the object. A piezoelectric motor 10r is mounted in the portion of the wrist 804 in a state where a driving convex portion 114 is pressed against the end surface of the wrist 804. For this reason, if the piezoelectric motor 10r is operated, it is possible to rotate the entire base 802.

FIG. 20 is an explanatory view illustrating a robot 850 including the robot hand 800. As shown in the drawing, the robot 850 includes a plurality of arms 810, and joint portions 820 which connect the arms 810 in a bendable state. The robot hand 800 is connected to the tip of the arm 810. Each joint portion 820 is embedded with a piezoelectric motor 10j as an actuator for bending the joint portion 820. For this reason, if the piezoelectric motor 10j is operated, it is possible to bend each joint portion 820 by an arbitrary angle.

Although the piezoelectric motor according to the embodiment of the invention or various devices having the piezoelectric motor mounted therein have been described, the invention is not limited to the foregoing example, modifications, and application examples, and may be carried out in various forms without departing from the scope of the invention.

The entire disclosure of Japanese Patent Application No. 2011-266556 filed Dec. 6, 2011 is hereby expressly incorporated by reference herein in its entirety.

What is claimed is:

1. A piezoelectric motor which vibrates a vibrating body and contains a piezoelectric material and brings a convex portion protruding from an end surface of the vibrating body into contact with an object to move the object, the piezoelectric motor comprising:
a vibrating body case which accommodates the vibrating body;
a base which has a slide portion on which the vibrating body case slides, and to which the vibrating body case is attached;
a pressing elastic body which presses the convex portion protruding from the vibrating body case toward the object; and
a side pressure elastic body which presses the vibrating body case toward the slide portion of the base from a direction intersecting a sliding direction of the vibrating body case,
wherein an end surface of the side pressure elastic body in contact with the vibrating body case is fitted into the vibrating body case.

2. The piezoelectric motor according to claim 1,
wherein the base includes a side pressure elastic body retention portion which supports an end surface of the side pressure elastic body not in contact with the vibrating body case, and
an end surface of the side pressure elastic body in contact with the side pressure elastic body retention portion is fitted into the side pressure elastic body retention portion.

3. The piezoelectric motor according to claim 2,
wherein the pressing elastic body is provided on a side on which the slide portion is provided with respect to the vibrating body case or a side on which the side pressure elastic body is provided.

4. A driving device comprising:
the piezoelectric motor according to claim 3.

5. A printing device comprising:
the piezoelectric motor according to claim 3.

6. A robot hand comprising:
the piezoelectric motor according to claim 3.

7. A robot comprising:
the robot hand according to claim 6.

8. An electronic component inspection device which mounts a held electronic component in an inspection socket, and inspects the electrical characteristics of the electronic component,
wherein the electronic component is aligned with respect to the inspection socket by the piezoelectric motor according to claim 3.

9. An electronic component conveying device which conveys a held electronic component,
wherein the electronic component is aligned by the piezoelectric motor according to claim 3.

10. An electronic component conveying device comprising:
a holding device which holds an electronic component;
a moving device which moves the holding device in the directions of three axes in total of a first axis and a second axis perpendicular to each other and a third axis perpendicular to the first axis and the second axis; and
a control device which controls the operation of the moving device,
wherein the holding device is embedded with a first piezoelectric motor which moves the electronic component in the direction of the first axis, a second piezoelectric motor which moves the electronic component in the direction of the second axis, and a third piezoelectric motor which rotates the electronic component around the third axis, and
the first to third piezoelectric motors are the piezoelectric motor according to claim 3.

11. An electronic component inspection device comprising:
an inspection socket in which an electronic component is mounted, and the electrical characteristics of the electronic component are inspected;
a holding device which holds the electronic component;
a moving device which moves the holding device in the directions of three axes in total of a first axis and a second axis perpendicular to each other and a third axis perpendicular to the first axis and the second axis;
an imaging device which is provided on the first axis or the second axis when viewed from the inspection socket to detect the posture of the electronic component mounted in the inspection socket;
an upstream-side stage which conveys the electronic component from the inspection socket to a predetermined position on the first axis or the second axis connecting the imaging device;
a downstream-side stage which conveys the electronic component from a predetermined position opposite to the side on which the imaging device is provided when viewed from the inspection socket; and
a control device which controls the operation of the moving device,
wherein the control device includes:
a first control unit which moves the holding device holding the electronic component conveyed by the upstream-side stage onto the imaging device,
a second control unit which moves the holding device to mount the electronic component whose posture is confirmed by the imaging device in the inspection socket, and
a third control unit which moves the holding device to place the electronic component whose electrical characteristics are inspected in the inspection socket from the inspection socket to the downstream-side stage,
the holding device is embedded with a first piezoelectric motor which moves the electronic component in the direction of the first axis on the basis of the posture of the electronic component detected by the imaging device, a second piezoelectric motor which moves the electronic component in the direction of the second axis on the basis of the posture of the electronic component detected by the imaging device, and a third piezoelectric motor which rotates the electronic component around the third axis on the basis of the posture of the electronic component detected by the imaging device, and
each of the first to third piezoelectric motors is the piezoelectric motor according to claim 3.

12. An electronic component inspection device which mounts a held electronic component in an inspection socket, and inspects the electrical characteristics of the electronic component, comprising:
a piezoelectric motor which aligns the electronic component with respect to the inspection socket,
wherein the piezoelectric motor includes:
a vibrating body which contains a piezoelectric material, and has a convex portion protruding from an end surface,
a vibrating body case which accommodates the vibrating body,
a base which has a slide portion on which the vibrating body case slides, and to which the vibrating body case is attached,
a pressing elastic body which presses the convex portion protruding from the vibrating body case toward the object, and
a side pressure elastic body which presses the vibrating body case toward the slide portion of the base from a direction intersecting a sliding direction of the vibrating body case, and
an end surface of the side pressure elastic body on a side in contact with the vibrating body case is fitted into the vibrating body case.

13. An electronic component conveying device which conveys a held electronic component, the electronic component conveying device comprising:
a piezoelectric motor which aligns the electronic component,
wherein the piezoelectric motor includes:
a vibrating body which contains a piezoelectric material, and has a convex portion protruding from an end surface,
a vibrating body case which accommodates the vibrating body,
a base which has a slide portion on which the vibrating body case slides, and to which the vibrating body case is attached,
a pressing elastic body which presses the convex portion protruding from the vibrating body case toward the object, and
a side pressure elastic body which presses the vibrating body case toward the slide portion of the base from a direction intersecting a sliding direction of the vibrating body case, and
an end surface of the side pressure elastic body on a side in contact with the vibrating body case is fitted into the vibrating body case.

14. A piezoelectric motor comprising:
a piezoelectric vibrating body;
a protrusion protruding from an end of the vibrating body and adapted to move in an elliptical pattern due to the actuation of the piezoelectric body;
a case supporting the vibrating body;
a base slidably supporting the case;
a first biasing member disposed between the base and the case and pressing the case in a first direction substantially axially aligned with the protrusion; and
a second biasing member disposed between the base and the case and pressing the case in a second direction substantially orthogonal to the first direction,
wherein a first end of the second biasing member is non-slidably fixed within a recess of the case.

15. The piezoelectric motor according to claim 14,
wherein a second end of the second biasing member opposite the first end is non-slidably fixed within a retention recess of the base.

16. The piezoelectric motor according to claim 15,
wherein the base has an opening accommodating the second biasing member therein, and the retention recess of the base is formed in an end surface of the opening.

17. The piezoelectric motor according to claim 14,
wherein the first and second biasing members are springs.
